(19) United States
(12) Patent Application Publication
(10) Pub. No.: US 2026/0133138 A1
(43) Pub. Date: May 14, 2026

(54) FLUX APPLICATION STATE INSPECTION APPARATUS AND FLUX APPLICATION STATE INSPECTION METHOD

(71) Applicant: CKD Corporation, Aichi (JP)

(72) Inventors: Kensuke Takamura, Aichi (JP); Satoshi Kanbe, Aichi (JP); Shiori Imaizumi, Aichi (JP); Manabu Okuda, Aichi (JP)

(73) Assignee: CKD Corporation, Aichi (JP)

(21) Appl. No.: 19/443,274

(22) Filed: Jan. 8, 2026

Related U.S. Application Data
(63) Continuation of application No. PCT/JP2024/033284, filed on Sep. 18, 2024.

(30) Foreign Application Priority Data
Oct. 27, 2023 (JP) 2023-184937

(51) Int. Cl. G01N 21/956; G01N 21/88

(52) U.S. Cl. CPC G01N 21/95684; G01N 21/8806

(57) ABSTRACT

A flux application state inspection device includes an illumination device that irradiates, with ultraviolet light, a circuit board having electrodes on which a flux capable of absorbing the ultraviolet light is applied; an imaging device that takes an image of the ultraviolet light radiated to the circuit board; and a central processing unit (CPU) that: sets, with a reference portion of the circuit board as a reference, an inspection area on the circuit board for each component to be mounted on the circuit board, wherein the inspection area corresponds to the component and includes two or more of the electrodes on which the component is mounted, and detects whether an application state of the flux is defective or non-defective, based on the image obtained by the imaging device while the inspection area is irradiated with the ultraviolet light by the illumination device.

### BACKGROUND

### Technical Field

The present disclosure relates to an inspection device and an inspection method of performing an inspection for the application state of flux on a circuit board.

### Description of Related Art

A general procedure of mounting an electronic component on a printed circuit board first prints solder paste on electrodes that are placed on the printed circuit board. The procedure then temporarily fixes an electronic component on the printed circuit board with the solder paste printed thereon by taking advantage of the viscosity of the solder paste. After temporary fixation of the electronic component, the printed circuit board is introduced into a reflow furnace to pass through a predetermined reflow process. This achieves soldering of the electronic component.

With a view to downsizing and reducing the occurrence of a mounting failure, a semiconductor package, such as a ball grid array (BGA), having a plurality of bumps in a spherical shape (solder balls) arrayed regularly on a bottom face thereof has been proposed as the electronic component. In the case of mounting such a semiconductor package as the electronic component on the printed circuit board, there is no need to print the solder paste, but there is only a need to place the bumps relative to the electrodes. In the case of mounting such a semiconductor package on the printed circuit board, however, it is preferable to apply flux to the electrodes, in order to enhance the wettability of solder, before the pumps are placed on the electrodes.

An inappropriate application state of the flux to the electrodes is likely to cause a defect, for example, an insufficient joint strength of the electronic component with the printed circuit board. It is accordingly preferable to perform in advance an inspection for the application state of the flux, before the electronic component is placed on the printed circuit board. A known inspection device used to perform an inspection for the application state of the flux compares an image of the flux taken by an imaging device with pattern-recognized electrodes (a circuit pattern) and performs an inspection for the application state of the flux (as described in, for example, Patent Literature 1).

In the inspection device described in the above Patent Literature 1, the area of the applied flux is set to be wider than the entire area of the electrodes (the entire area of a printed circuit), and furthermore, the flux is opaque. This configuration thus allows an image of the flux to be taken by the imaging device but does not allow an image of the electrodes (an image of the printed circuit) with the flux applied thereon to be taken by the imaging device. An inspection for the application state of the flux accordingly utilizes the patterned-recognized electrodes, instead of the actual electrodes, as the inspection area. In other words, an inspection for the application state of the flux is performed by using a virtually estimated existence region of electrodes. In order to assure the sufficiently high accuracy of inspection, there is a need to set an appropriate inspection area suitable for the position of the actual electrodes.

One proposed technique for setting the appropriate inspection area suitable for the position of the actual electrodes is, for example, a method of using marks provided on a printed circuit board as a reference (as described in, for example, Patent Literature 2).

### PATENT LITERATURE

Patent Literature 1: Japanese Patent No. 2010-271165A

Patent Literature 2: Japanese Patent No. 2005-286309A

In the method of using marks as a reference, however, an extremely high processing accuracy may be required to set an appropriate inspection area in the case of an inspection of a printed circuit board where a plurality of electrodes are provided at extremely small pitches (for example, a printed circuit board with a semiconductor package, such as a BGA, mounted thereon). Such requirement for the extremely high processing accuracy is likely to increase the processing load and thereby decrease the efficiency of inspection.

Simplification of the processing for the purpose of relieving the processing load is, on the other hand, likely to cause a “deviation” between the inspection area and the position of the actual electrodes. As a result, this is likely to fail in providing the sufficiently high accuracy of inspection.

### SUMMARY

By taking into account the circumstances described above, one or more embodiments of the present disclosure provide, for example, a flux application state inspection device that achieves the high accuracy of inspection, while enabling an inspection area to be set by a relatively simple process.

The following describes each of various aspects of the present disclosure. Functions and advantageous effects that are characteristic of each of the aspects are also described as appropriate.

Aspect 1. There is provided a flux application state inspection device that comprises an illumination device that irradiates, with ultraviolet light, a circuit board having electrodes on which a flux capable of absorbing the ultraviolet light is applied; an imaging device that takes an image of the ultraviolet light radiated to the circuit board; and a central processing unit (CPU) that: sets, with a reference portion of the circuit board as a reference, an inspection area on the circuit board for each component to be mounted on the circuit board, wherein the inspection area corresponds to the component and includes two or more of the electrodes on which the component is mounted, and detects whether an application state of the flux is defective or non-defective, based on the image obtained by the imaging device while the inspection area is irradiated with the ultraviolet light by the illumination device, wherein the CPU calculates an area of a high-luminance part of the inspection area having luminance equal to or higher than a predetermined luminance threshold value, and detects whether the application state of the flux is defective or non-defective based on the calculated area.

In the flux application state inspection device of above Aspect 1, the CPU sets an inspection area that corresponds to a component to be mounted and that includes a plurality of electrodes which the component is mounted on. For example, when the component to be mounted is a BGA and is to be mounted on a plurality of electrodes, an area including these electrodes is set as an inspection area. In other words, each of the individual electrodes is not set as one inspection area, but one inspection area is set corresponding to a plurality of electrodes which one electronic component is to be mounted on. This configuration allows the inspection area to be set relatively roughly and thus enables the inspection area to be set by a relatively simple process. This reduces the processing load and improves the efficiency of inspection.

Furthermore, in the flux application state inspection device of above Aspect 1, the CPU calculates the area of a high-luminance part having luminance equal to or higher than a predetermined luminance threshold value in each inspection area and determines the application state of the flux, based on the calculated area. The ultraviolet light is absorbed by the flux but is reflected by the electrode, so that the flux is expected to form a dark portion and the electrode is expected to form a bright portion in the taken image. The CPU of Aspect 1 calculates the area of an electrode that is not covered with the flux (although the electrode is to be covered with the flux), as the area of the high-luminance part having the luminance equal to or higher than the luminance threshold value. The CPU then performs an inspection for the application state of the flux, based on the area of the high-luminance part having the luminance equal to or higher than the luminance threshold value (i.e., the area of the electrode that is not covered with the flux). This configuration enables an inspection for the application state of the flux to be performed not with regard to each of a plurality of electrodes corresponding to one electronic component individually but with regard to all these electrodes collectively. This accordingly achieves the high accuracy of inspection, while setting the inspection area relatively roughly. Even in the case of an inspection for a circuit board provided with a plurality of electrodes arranged at extremely small pitches (for example, a circuit board with a BGA mounted thereon), this configuration assures the sufficiently high accuracy of inspection.

Aspect 2. In the flux application state inspection device described in above Aspect 1, the ultraviolet light radiated from the illumination device may have a wavelength set to be not lower than 100 nm and not higher than 300 nm.

The configuration of above Aspect 2 causes the flux to readily absorb the more ultraviolet light. This accordingly causes the flux to appear in a darker state in the taken image and thereby increases a difference between the luminance of the electrodes and the luminance of the flux in the taken image. This enables the flux and the electrodes to be more accurately specified and thereby further enhances the accuracy of inspection.

In terms of further enhancing the accuracy of inspection, the wavelength of the ultraviolet light is more preferably not lower than 200 nm and not higher than 300 nm, is furthermore preferably not lower than 220 nm and not higher than 280 nm, and is most preferably not lower than 230 nm and not higher than 260 nm.

Aspect 3. In the flux application state inspection device described in above Aspect 1, the imaging device may be placed above the circuit board such that an optical axis of the imaging device is perpendicular to the circuit board, and the ultraviolet light radiated from the illumination device to the circuit board may have an incident angle of not less than 0 degree and not greater than 30 degrees.

The configuration of above Aspect 3 causes the ultraviolet light reflected by the electrodes to more readily reach the imaging device. This configuration accordingly further increases a difference between the luminance of the electrodes and the luminance of the flux in the taken image. As a result, this enables the flux and the electrodes to be more accurately specified in the taken image and further enhances the accuracy of inspection.

In terms of further enhancing the accuracy of inspection, the incident angle of the ultraviolet light to the circuit board is more preferably not less than 0 degree and not greater than 20 degrees, is furthermore preferably not less than 0 degree and not greater than 15 degrees, and is mot preferably not less than 0 degree and not greater than 10 degrees.

Aspect 4. The flux application state inspection device described in above Aspect 1 may be used for inspecting the flux that is transparent or translucent.

The illumination device is configured to radiate not visible light but ultraviolet light. Even when the flux is transparent or translucent, the configuration of above Aspect 4 enables the flux to be observed as a dark portion in the taken image. This configuration thus enables an inspection for the application state of the flux to be performed with high accuracy even when the flux as an object of inspection is transparent or translucent.

Aspect 5. The flux application state inspection device described in above Aspect 1 may be used for inspecting the flux that is applied to an electrode of a glass epoxy substrate used for the circuit board.

The configuration of above Aspect 5 causes the brightness and the darkness of the electrodes and the circuit board (more specifically, a base material portion thereof) to be more distinctively observable in the taken image and thus enables the area of the bright portions (the electrodes) to be more accurately specified. This further enhances the accuracy of inspection.

Aspect 6. There is provided a flux application state inspection method that comprises: an irradiation process of irradiating, with ultraviolet light, a circuit board having electrodes on which a flux capable of absorbing the ultraviolet light is applied; an imaging process of taking an image of the ultraviolet light radiated to the circuit board; an inspection area setting process of setting, with a reference portion of the circuit board as a reference, an inspection area on the circuit board for each component to be mounted on the circuit board, wherein the inspection area corresponds to the component and includes two or more of the electrodes on which the component is mounted, and a detection process of detecting whether an application state of the flux is defective or non-defective, based on the image obtained by the imaging process while the inspection area is irradiated with the ultraviolet light by the irradiation process, wherein the detection process calculates an area of a high-luminance part of the inspection area having luminance equal to or higher than a predetermined luminance threshold value, and detects whether the application state of the flux is defective or non-defective based on the calculated area.

The configuration of above Aspect 6 has similar functions and advantageous effects to those of Aspect 1 described above.

The technical features described above in the respective aspects may be combined appropriately. For example, the technical features with regard to above Aspect 4 may be combined with the technical features with regard to above Aspect 2. In another example, at least one of the technical features with regard to above Aspects 2 to 5 may be applied to above Aspect 6.

### BRIEF DESCRIPTION OF DRAWINGS

FIG. 1 is a schematic plan view illustrating a printed circuit board;

FIG. 2 is a schematic plan view illustrating the printed circuit board with omission of electronic components and the like to show electrodes;

FIG. 3 is a schematic sectional view illustrating partial closeup of the printed circuit board;

FIG. 4 is a schematic perspective view illustrating an electronic component;

FIG. 5 is a sectional view illustrating partial closeup of the electronic component and the like before being mounted on electrodes;

FIG. 6 is a block diagram showing the configuration of a production line of the printed circuit board;

FIG. 7 is a schematic plan view illustrating partial closeup of the printed circuit board to show flux applied on the electrodes;

FIG. 8 is a schematic configuration diagram schematically illustrating a flux application state inspection device;

FIG. 9 is a block diagram showing the functional configuration of the flux application state inspection device;

FIG. 10 is a schematic plan view illustrating partial closeup of the printed circuit board in the case where the entirety of a plurality of electrodes configuring one electrode group is collectively and appropriately covered with flux;

FIG. 11 is a schematic diagram illustrating a luminance image in the case where the entirety of the plurality of electrodes configuring one electrode group is collectively and appropriately covered with flux;

FIG. 12 is a schematic plan view illustrating partial closeup of the printed circuit board in the case where part of the plurality of electrodes is not appropriately covered with flux but is exposed;

FIG. 13 is a schematic diagram illustrating a luminance image in the case where part of the plurality of electrodes is not appropriately covered with flux but is exposed;

FIG. 14 is a schematic plan view illustrating partial closeup of the printed circuit board in a configuration that a plurality of electrodes are individually covered with flux, in the case where part of the plurality of electrodes is not appropriately covered with flux but is exposed; and

FIG. 15 is a schematic diagram illustrating a luminance image in the configuration that the plurality of electrodes are individually covered with flux, in the case where part of the plurality of electrodes is not appropriately covered with flux but is exposed.

### DETAILED DESCRIPTION OF EMBODIMENTS

The following describes embodiments with reference to drawings. The configuration of a printed circuit board as the “circuit board” is described first.

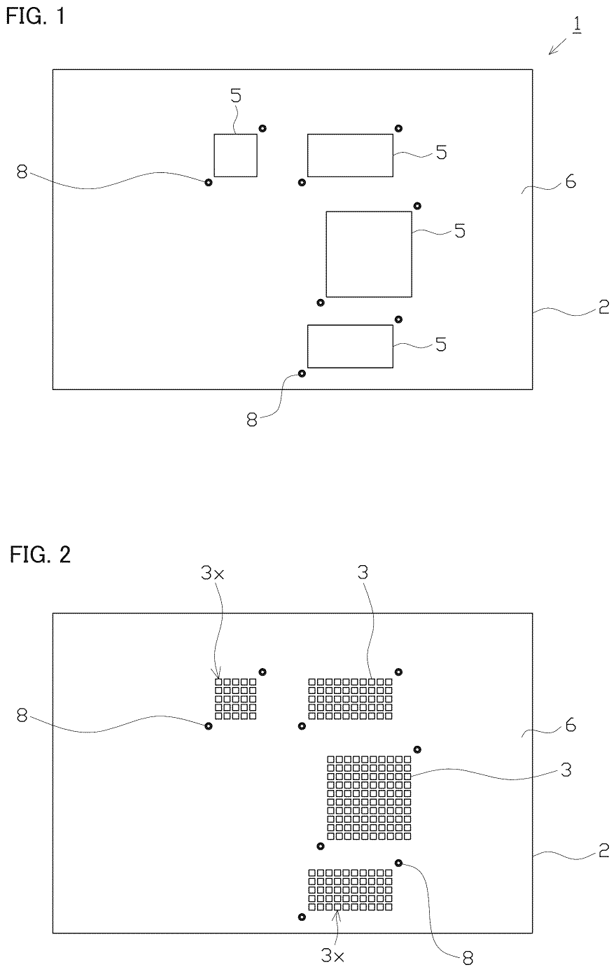

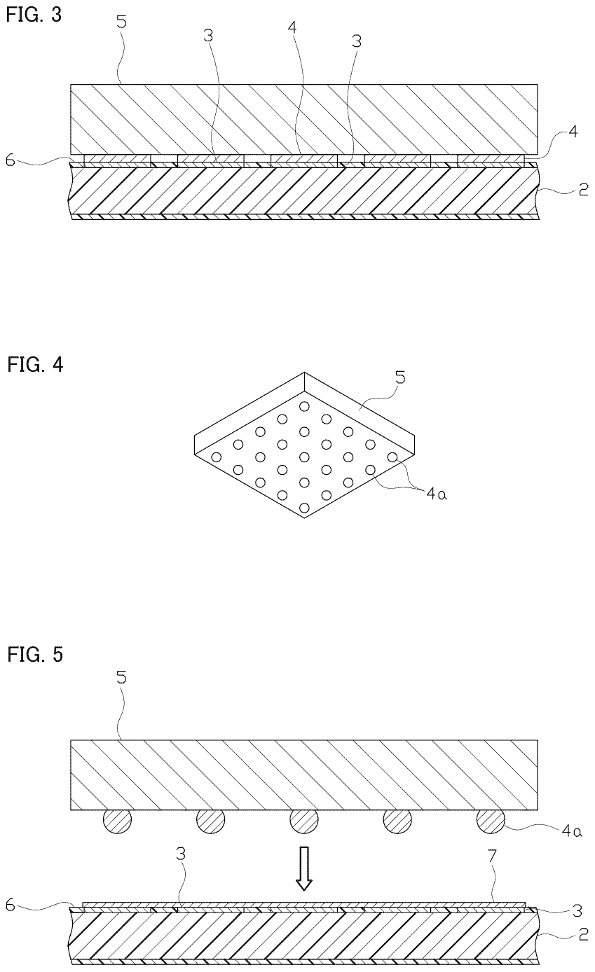

As shown in FIG. 1 to FIG. 3, a printed circuit board 1 (hereinafter simply referred to as the “circuit board 1”) is a glass epoxy circuit board where electrodes 3 (not shown in FIG. 1) made of copper foil and the like are formed on a flat plate-like base substrate 2 made of, for example, a glass epoxy resin. An electronic component 5, such as a chip, is mounted on the electrodes 3 via solder 4 that is provided by kneading solder grains with flux. According to one or more embodiments, the electronic component 5 corresponds to the “component”.

A region of the base substrate 2 other than the electrodes 3 and a circuit pattern (electrode pattern) is a base material portion 6 comprised of, for example, a glass epoxy resin and a resist, and gives green color according to one or more embodiments.

Furthermore, as shown in FIG. 4, the electronic component 5 according to one or more embodiments is a ball grid array (BGA) where a plurality of bumps 4a are arrayed regularly on a bottom face of the electronic component 5. The respective bumps 4a are fused to be spread over the surface of the electrodes 3 in a reflow process performed by a reflow device 14 described later and eventually forms the solder 4. The base substrate 2 has an electrode group 3x (shown in FIG. 2) consisting of a plurality of electrodes 3 as objects which the respective bumps 4a are placed on for mounting one electronic component 5. In a process of mounting an electronic component 5 on the base substrate 2, each bump 4a is placed on each of the electrodes 3 configuring the electrode group 3x. The base substrate 2 has a plurality of (for example, four) electrode groups 3x, and one electronic component 5 is mounted on each electrode group 3x. According to one or more embodiments, the pitch of the plurality of electrodes 3 configuring one electrode group 3x is very small (for example, as small as 1.8 mm or less or 0.5 mm or less).

Moreover, as shown in FIG. 5, before the electronic component 5 is mounted on the electrode group 3x, flux 7 is applied in advance on a surface of the base substrate 2 including surface of the electrode group 3x (the electrodes 3). The flux 7 is used to remove metal oxide films in the electrodes 3, the electronic component 5, and the solder 4 and enhance the wettability of the solder 4. The flux 7 is configured to absorb ultraviolet rays and to be transparent or translucent and hardly visible. Furthermore, according to one or more embodiments, the flux 7 is configured not to individually cover the plurality of electrodes 3 configuring one electrode group 3x but to collectively cover all these electrodes 3.

The base substrate 2 is further provided with marks 8 for specifying a mounting position of the electronic component 5 (as shown in FIG. 1 and FIG. 2). The marks 8 are provided in portions of the base substrate 2 that are not covered with the flux 7 and are also used to specify an inspection area KR described later. According to one or more embodiments, the mark 8 corresponds to a “reference portion”. A predetermined electrode 3, a circuit pattern (electrode pattern) or a printed portion may also be used as the “reference portion”.

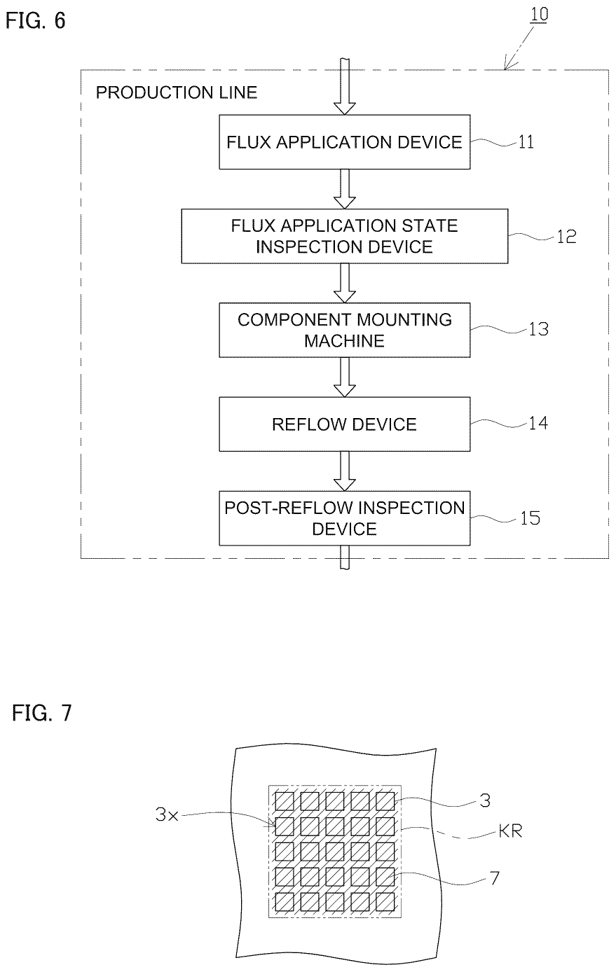

The following describes a production line (manufacturing process) of manufacturing the circuit board 1. As shown in FIG. 6, in a production line 10, a flux application device 11, a flux application state inspection device 12, a component mounting machine 13, a reflow device 14 and a post-reflow inspection device 15 are placed sequentially from an upstream side thereof (from an upper side of FIG. 6). The circuit board 1 is set to be transferred to these devices in this sequence.

The flux application device 11 is configured to apply the flux 7 on at least the surface of the electrodes 3 of the circuit board 1. For example, the flux application device 11 places a predetermined mask on the circuit board 1 and then applies the flux 7 on the surface of the electrodes 3 by utilizing screen printing. In another example, the flux application device 11 may use a predetermined dispenser to apply the flux.

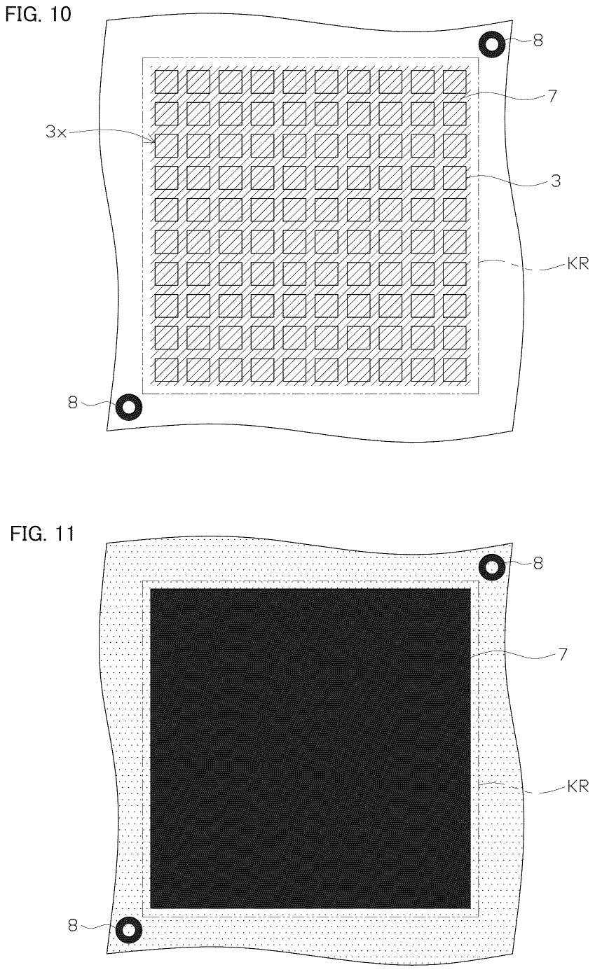

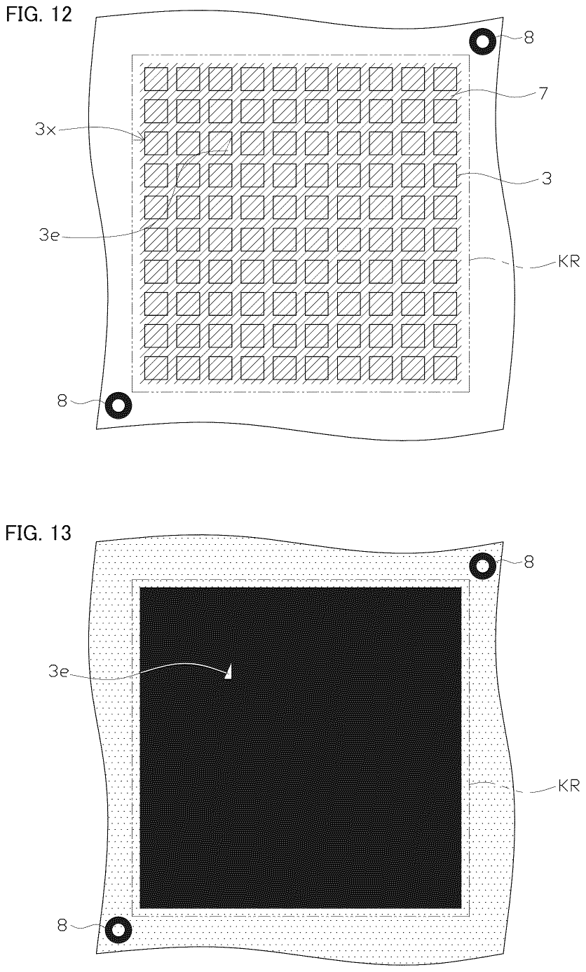

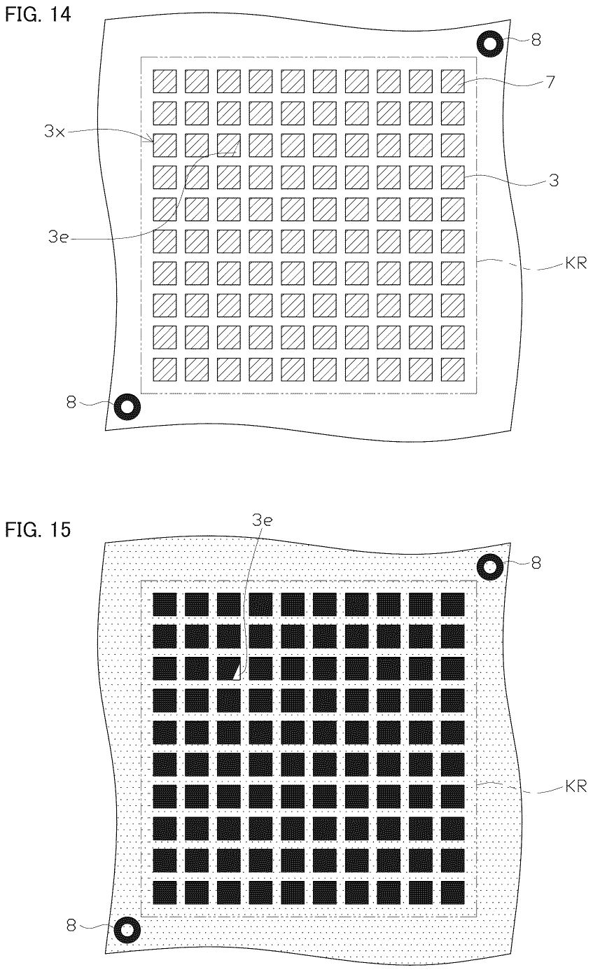

As shown in FIG. 7, the flux application device 11 applies the flux 7 such as to collectively cover the plurality of electrodes 3 configuring one electrode group 3x. FIG. 7, FIG. 10, FIG. 12, and FIG. 14 are schematic plan views illustrating partial closeup of the circuit board 1. In these drawings, the flux 7 is shown by slant lines for convenience of illustration. The flux 7 is, however, transparent or translucent. In the actual state, there is accordingly a difficulty in clearly specifying an application area of the flux 7 by visual observation.

The flux application state inspection device 12 is configured to perform an inspection for the application state of the flux 7 that is applied on the electrodes 3. The flux application state inspection device 12 will be described later.

The component mounting machine 13 is configured to perform a component mounting process (mounting process) that mounts the electronic component 5 on the electrodes 3 and the like. The electronic component 5 is accordingly mounted on the electrode group 3x via the bumps 4a.

The reflow device 14 is configured to perform a reflow process that heats and fuses the bumps 4a and the like. In the circuit board 1 subjected to the reflow process, the bumps 4a are fused to be spread over the surface of the electrodes 3 and are eventually solidified to form the solder 4. The solder 4 works to join the electronic component 5 with the electrodes 3.

The post-reflow inspection device 15 is configured to perform a post-reflow inspection process that performs an inspection to determine whether the solder joint is appropriately provided or not in the reflow process. For example, the post-reflow inspection device 15 uses image data or the like of the circuit board 1 after the reflow process to check the presence or the absence of any positional misalignment in the electronic component 5.

The production line 10 is further provided with conveyors or the like between the respective devices described above, for example, between the flux application device 11 and the flux application state inspection device 12, to transfer the circuit board 1, although the illustration is omitted. Furthermore, a branching device is provided between the flux application state inspection device 12 and the component mounting machine 13 and on a downstream side of the post-reflow inspection device 15. The circuit board 1 determined as non-defective by the flux application state inspection device 12 and by the post-reflow inspection device 15 is guided directly to the downstream side. The circuit board 1 determined as defective by at least one of the inspection devices 12 and 15 is, on the other hand, discharged by the branching device to a defective storage (not shown).

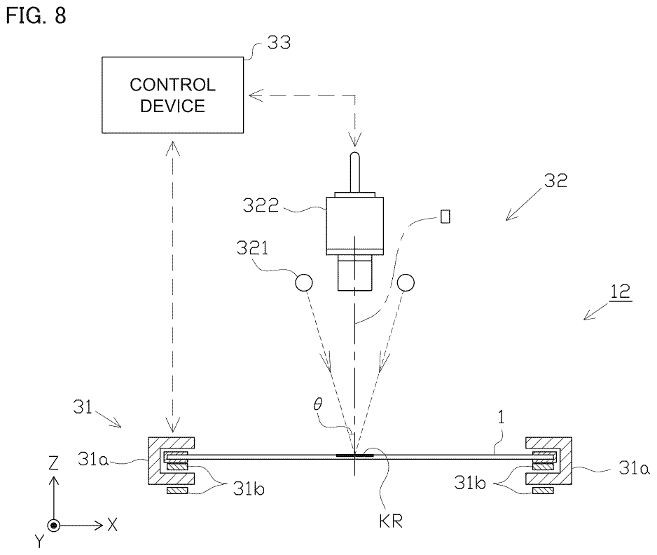

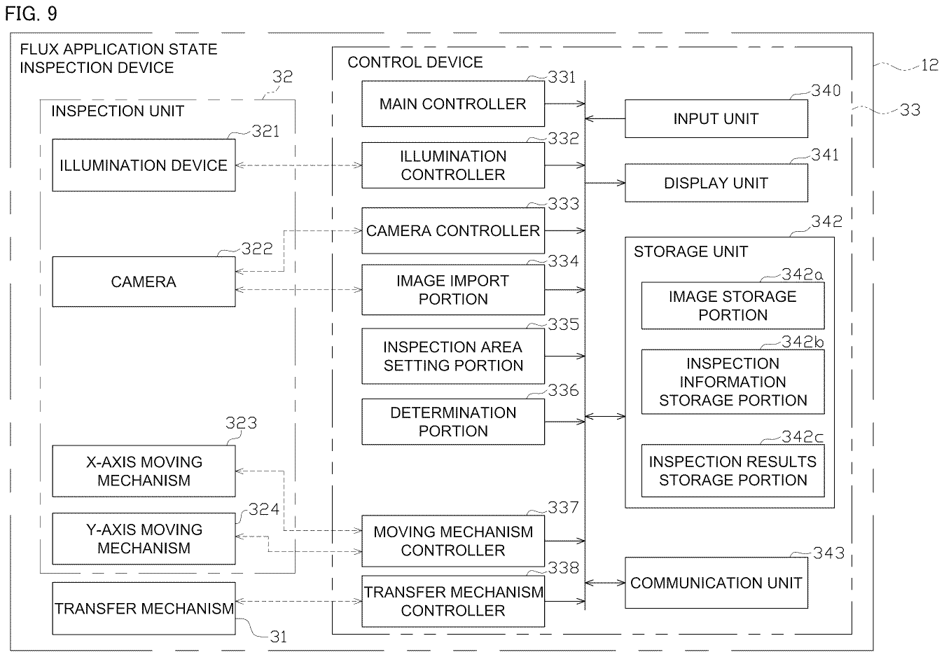

The following describes the configuration of the flux application state inspection device 12. As shown in FIG. 8 and FIG. 9, the flux application state inspection device 12 includes a transfer mechanism 31 configured to, for example, transfer the circuit board 1 and position the circuit board 1; an inspection unit (or inspector) 32 configured to perform an inspection of the flux 7; and a control device 33 configured to drive and control the transfer mechanism 31 and the inspection unit 32 and to perform a variety of controls, image processing, and arithmetic processing in the inspection device 12.

The transfer mechanism 31 includes one pair of transfer rails 31a placed along a carrying in/out direction of the circuit board 1; and an endless conveyor belt 31b placed to be rotatable relative to each of the transfer rails 31a. The transfer mechanism 31 is also provided with a driving unit, such as a motor, configured to drive the conveyor belt 31b and with a chuck mechanism configured to position the circuit board 1 at a predetermined position, although the illustration is omitted. The transfer mechanism 31 is driven and controlled by the control device 33 (more specifically, a transfer mechanism controller 338 thereof described later).

Under the configuration described above, the circuit board 1 carried into the flux application state inspection device 12 is placed on the conveyor belt 31b in the state that respective edges of the circuit board 1 in a width direction perpendicular to the carrying in/out direction are respectively inserted into the transfer rails 31a. The conveyor belt 31b subsequently starts operation, so as to transfer the circuit board 1 to a predetermined inspection position. When the circuit board 1 reaches the inspection position, the conveyor belt 31b stops, and the chuck mechanism described above starts operation. This operation of the chuck mechanism presses up the conveyor belt 31b and causes the respective edges of the circuit board 1 to be sandwiched between the conveyor belt 31b and upper sides of the transfer rails 31a. This positions and fixes the circuit board 1 at the inspection position. On completion of the inspection, the fixation by the chuck mechanism is released, and the conveyor belt 31b starts operation. The circuit board 1 is accordingly carried out from the flux application state inspection device 12. The configuration of the transfer mechanism 31 is, however, not limited to the configuration of the above embodiments, but another configuration may be employed.

The inspection unit 32 is placed above the transfer rails 31a (transfer path of the circuit board 1) and is provided with an illumination device (or illuminator) 321 and a camera 322. According to one or more embodiments, the illumination device 321 configures the “irradiation unit”, and the camera 322 configures the “imaging unit” or “imaging device”.

The inspection unit 32 is also provided with an X-axis moving mechanism 323 which may comprises an arm and/or X-axis rail(s), for example, and is configured to allow for a movement in an X-axis direction (a left-right direction of FIG. 8) and a Y-axis moving mechanism 324 which may comprises an arm and/or Y-axis rail(s), for example, and is configured to allow for a movement in a Y-axis direction (a front-back direction of FIG. 8). Both the moving mechanisms 323 and 324 are driven and controlled by the control device 33 (more specifically, a moving mechanism controller 337 thereof described later).

The illumination device 321 is configured to irradiate the circuit board 1, which is an object of inspection performed by the flux application state inspection device 12, with ultraviolet rays. The wavelength of the ultraviolet rays radiated from the illumination device 321 is set to be not lower than 100 nm and not higher than 300 nm. The wavelength of the ultraviolet rays is more preferably not lower than 200 nm and not higher than 300 nm, is furthermore preferably not lower than 220 nm and not higher than 280 nm, and is most preferably not lower than 230 nm and not higher than 260 nm.

Furthermore, the illumination device 321 irradiates the circuit board 1 with the light radiated from vertically above or from obliquely above. An incident angle θ of the ultraviolet rays radiated from the illumination device 321 toward the circuit board 1 (more specifically, an inspection area thereof) is set to be not less than 0 degree and not greater than 30 degrees. The incident angle θ is more preferably not less than 0 degree and not greater than 20 degrees, is furthermore preferably not less than 0 degree and not greater than 15 degrees, and is mot preferably not less than 0 degree and not greater than 10 degrees. According to one or more embodiments, a process of radiating the ultraviolet rays from the illumination device 321 toward the circuit board 1 corresponds to the “irradiation process”.

The camera 322 is placed immediately above the circuit board 1 as an object of inspection, such that an optical axis O of the camera O is orthogonal to the circuit board 1, and is configured to take an image of a predetermined inspection area KR (a rectangular area surrounded by two-dot chain line shown in, for example, FIG. 7) of the circuit board 1 from immediately above. According to one or more embodiments, the inspection area KR is set for each of the electronic components 5 to be mounted and is specified as an area including all the plurality of electrodes 3 constituting one electrode group 3x. The inspection area KR is set by an inspection area setting portion 335 described later.

The camera 322 is configured by, for example, a CCD camera having sensitivity to the ultraviolet rays radiated from the illumination device 321 and is operated and controlled by the control device 33 (more specifically, a camera controller 333 thereof described later). The operation control of the control device 33 causes the camera 322 to take an image of the ultraviolet rays reflected from the circuit board 1 in the inspection area KR in the state that the circuit board 1 is irradiated with the ultraviolet rays from the illumination device 321. A luminance image with regard to the inspection area KR is accordingly obtained. The luminance image includes a large number of pixels respectively having data with regard to the luminance. According to one or more embodiments, a process of causing the camera 322 to take an image of the ultraviolet rays radiated from the illumination device 321 and reflected from the circuit board 1 corresponds to the “imaging process”. The luminance image corresponds to the “taken image”.

In the case where all the plurality of electrodes 3 constituting one electrode group 3x are collectively and appropriately covered with the flux 7 (for example, as shown in FIG. 10), no electrode 3 appears but the flux 7 appears as a dark region in the inspection area KR of the luminance image (for example, as shown in FIG. 11). In the case where part or the entirety of the electrodes 3 is not appropriately covered with the flux 7 but there is any exposed electrode 3e, which is an electrode 3 exposed, (for example, as shown in FIG. 12), on the other hand, the exposed electrode 3e appears as a bright region in the inspection area KR of the luminance image (for example, as shown in FIG. 13). In the configuration that the plurality of electrodes 3 are individually covered with the flux 7, in the case where part of the electrodes 3 is not appropriately covered with the flux 7 but there is any exposed electrode 3e (for example, as shown in FIG. 14), the exposed electrode 3e appears as a bright region in the inspection area KR of the luminance image (for example, as shown in FIG. 15).

The luminance image obtained by the camera 322 is transferred to the control device 33 (an image import portion 334 thereof described later). The control device 33 performs an inspection process for the application state of the flux 7, based on the luminance image.

The control device 33 is configured by a computer including a CPU (Central Processing Unit) which executes predetermined arithmetic operations, a ROM (Read Only Memory) which stores a variety of programs, fixed value data and the like, a RAM (Random Access Memory) where a variety of data are temporarily stored in the course of execution of various arithmetic operations, and peripheral circuits thereof.

The CPU operates according to the various programs, so that the control device 33 serves as various functional portions, such as a main controller 331, an illumination controller 332, a camera controller 333, an image import portion 334, an inspection area setting portion 335, a determination portion 336, a moving mechanism controller 337, and a transfer mechanism controller 338.

The respective functional portions described above are implemented by cooperation of various hardware components, such as the CPU, the ROM and the RAM, described above. There is no need to clearly distinguish the functions implemented by the hardware configuration from the functions implemented by the software configuration. Part or the entirety of these functions may be implemented by a hardware circuit, such as an IC. According to one or more embodiments, the inspection area setting portion 335 configures the “inspection area setting unit”, and the determination portion 336 configures the “determination unit”.

The control device 33 is further provided with an input unit (or input device) 340 that is configured by a keyboard and a mouse, a touch panel or the like; a display unit (or display device) 341 that is configured by a liquid crystal display or the like and that is provided with a display screen; a storage unit (or storage device) 342 that is configured to store a variety of data, programs, results of arithmetic operations, results of inspections and the like; and a communication unit 343 that is configured to send and receive various data to and from outside. The storage unit 342 and the communication unit 343 are described first.

The storage unit 342 is configured by a memory device, such as an HDD (Hard Disk Drive) or an SSD (Solid State Drive) to store various pieces of information. The storage unit 342 includes an image storage portion (or image storage) 342a, an inspection information storage portion (or inspection information storage) 342b, and an inspection results storage portion (or inspection results storage) 342c.

The image storage portion 342a is configured to store the luminance image taken and obtained by the camera 322. The image stored in the image storage portion 342a can be appropriately displayed on the display unit 341.

The inspection information storage portion 342b is configured to store various pieces of information used for the inspection of the flux 7. The inspection information storage portion 342b stores therein, for example, a variety of threshold values used for binarization of the luminance image and for defective/non-defective determination, design data, production data and the like. The design data and the production data include, for example, planned application areas of the flux 7, size of the flux 7 in an ideal application state (for example, the area and the contour length of the flux 7) and mounting areas of the electronic components 5.

The inspection results storage portion 342c is configured to store inspection results data of an inspection with regard to the application state of the flux 7 performed by the determination portion 336. The inspection results storage portion 342c also stores therein, for example, statistical data obtained by stochastic and statistic processing of the inspection results data. These inspection results data and statistical data can be appropriately displayed on the display unit 341.

The communication unit 343 is provided with, for example, a communication interface in conformity with a communications standard, such as a wired LAN (Local Area Network) and a wireless LAN and is configured to send and receive various data to and from the outside. For example, results of an inspection performed by the determination portion 336 are output to the outside via the communication unit 343. Results of an inspection performed by the post-reflow inspection device 15 are input via the communication unit 343.

The following describes the above respective functional portions of the control device 33. More specifically, the following first describes the moving mechanism controller 337 and the transfer mechanism controller 338 and then describes the main controller 331 and the other functional portions.

The moving mechanism controller 337 is a functional portion of driving and controlling the X-axis moving mechanism 323 and the Y-axis moving mechanism 324 and is configured to control the position of the inspection unit 32, based on a command signal from the main controller 331. The moving mechanism controller 337 drives and controls the X-axis moving mechanism 323 and the Y-axis moving mechanism 324, such as to move the inspection unit 32 to a position above an arbitrary inspection area KR in the circuit board 1 that is positioned and fixed at the inspection position. The inspection unit 32 is sequentially moved to a plurality of inspection areas KR set in the circuit board 1 and sequentially performs inspections with regard to the plurality of inspection areas KR. This implements an inspection for the flux 7 in all the inspection areas KR.

The transfer mechanism controller 338 is a functional portion of driving and controlling the transfer mechanism 31 and is configured to control the transfer position of the circuit board 1, based on a command signal from the main controller 331.

The following describes the main controller 331 and the other functional portions. The main controller 331 is a functional portion of controlling the entirety of the flux application state inspection device 12 and is configured to send and receive a variety of signals to and from the other functional portions including the illumination controller 332 and the camera controller 333.

The illumination controller 332 is a functional portion of driving and controlling the illumination device 321. The illumination controller 332 is configured to perform, for example, timing control relating to radiation of light and stop of radiation from the illumination device 321 toward the circuit board 1, based on a command signal from the main controller 331.

The camera controller 333 is a functional portion of driving and controlling the camera 322. The camera controller 333 is configured to control, for example, the timing of an imaging operation of the camera 322, based on a command signal from the main controller 331.

The image input portion 334 is a functional portion of importing the luminance image taken and obtained by the camera 322. The luminance image imported by the image import portion 334 is stored into the image storage portion 342a.

The inspection area setting portion 335 is configured to set an inspection area KR with respect to each electronic component 5 by using the marks 8 provided in the circuit board 1 as a reference. According to one or more embodiments, the inspection area setting portion 335 sets an inspection area KR corresponding to a planned application area of the flux 7. More specifically, the inspection area setting portion 335 obtains a planned application area of the flux 7, based on the predetermined marks 8 provided in the circuit board 1 and the design data and the production data stored in the inspection information storage portion 342b and sets the inspection area KR from the planned application area thus obtained. According to one or more embodiments, the inspection area KR is set as an area slightly larger than the planned application area of the flux 7 and as an area including all the electrodes 3 where the flux 7 is planned to be applied. According to one or more embodiments, a process of causing the inspection area setting portion 335 to set the inspection area KR corresponds to the “inspection area setting process”. The inspection area KR may be set, based on a mounting area of each electronic component 5 on the design data and the production data.

The determination portion 336 is configured to perform an inspection for the flux 7 applied on the circuit board 1. More specifically, the determination portion 336 first performs a binarization process of a luminance image, based on a threshold value stored in the inspection information storage portion 342b, so as to obtain a binarized image. In the binarized image, a location corresponding to the flux 7 forms a dark portion (0), and a location corresponding to the electrode 3 that is not covered with the flux 7 but that is exposed on the outside forms a bright portion (1).

The determination portion 336 subsequently performs a process of specifying connecting regions of pixels corresponding to bright portions in the binarized image and calculates an area (the number of pixels according to one or more embodiments) of each of the specified connecting regions (each of lump parts). As a result, the determination portion 336 calculates the area of a part that is not covered by the flux 7 in each of the plurality of electrodes 3 configuring the electrode group 3x.

The determination portion 336 then compares the calculated area of each lump part with an area threshold value stored in advance in the inspection area storage portion 342b. When the area of at least one lump part is equal to or larger than the area threshold value, the determination portion 336 determines that application of the flux 7 to at least one electrode 3 is insufficient and thereby determines the application state of the flux 7 as “defective”. When the areas of all the lump parts are less than the area threshold value, on the other hand, the determination portion 336 determines that the flux 7 is appropriately applied to all the plurality of electrodes 3 configuring one electrode group 3x and thereby determines the application state of the flux 7 as “non-defective”.

The determination portion 336 performs the above determination with regard to all the inspection areas KR. When the application state of the flux 7 is determined as “defective” with regard to at least one inspection area KR, the determination portion 336 determines that the circuit board 1 as an object of inspection has “defective” application state of the flux 7. When the application state of the flux 7 is determined as “non-defective” with regard to all the inspection areas KR as a result of the above determination for all the inspection areas KR, on the other hand, the determination portion 336 determines that the circuit board 1 as an object of inspection has “non-defective” application state of the flux 7. The results of the defective/non-defective determination (inspection results data) are stored in the inspection results storage portion 342c. According to one or more embodiments, a process of causing the determination portion 336 to perform the defective/non-defective determination with regard to the application state of the flux 7 corresponds to the “determination process”.

As described above in detail, according to one or more embodiments, the inspection area setting portion 335 does not set each of the individual electrodes 3 as an inspection area but sets one inspection area KR corresponding to a plurality of electrodes 3 which one electronic component 5 is to be mounted on. This configuration allows the inspection area KR to be set relatively roughly and thus enables the inspection area KR to be set by a relatively simple process. This reduces the processing load and improves the efficiency of inspection.

Furthermore, the determination portion 336 calculates the area of a part having the luminance equal to or higher than a predetermined luminance threshold value (a connecting region of bright portions) in each of the inspection areas KR and determines the application state of the flux 7, based on the calculated area. This configuration enables an inspection for the application state of the flux 7 to be performed not with regard to each of the plurality of electrodes 3 corresponding to one electronic component 5 individually but with regard to all these electrodes 3 collectively. This accordingly achieves the high accuracy of inspection, while setting the inspection area KR relatively roughly. Even in the case of an inspection for the circuit board 1 provided with a plurality of electrodes 3 arranged at extremely small pitches (for example, a circuit board with a BGA mounted thereon), this configuration assures the sufficiently high accuracy of inspection.

The wavelength of the ultraviolet rays radiated from the illumination device 321 is not lower than 100 nm and not higher than 300 nm. This causes the flux 7 to readily absorb the more ultraviolet rays. This accordingly causes the flux 7 to appear in a darker state in the luminance image and increases a difference between the luminance of the electrodes 3 and the luminance of the flux 7 in the luminance image. This enables the flux 7 and the electrodes 3 to be more accurately specified and thereby further enhances the accuracy of inspection.

Moreover, the incident angle θ of the ultraviolet rays radiated from the illumination device 321 toward the circuit board 1 is set to be not less than 0 degree and not greater than 30 degrees. This causes the ultraviolet rays reflected by the electrodes 3 to more readily reach the imaging unit. This configuration accordingly further increases the difference between the luminance of the electrodes 3 and the luminance of the flux 7 in the luminance image. As a result, this enables the flux 7 and the electrodes 3 to be more accurately specified in the luminance image and further enhances the accuracy of inspection.

Additionally, the illumination device 321 is configured to radiate not visible rays but ultraviolet rays. Even when the flux 7 is transparent or translucent, this enables the flux 7 to be observed as a dark portion in the luminance image. This configuration thus enables an inspection for the application state of the flux 7 to be performed with high accuracy even when the flux 7 as an object of inspection is transparent or translucent.

Furthermore, the circuit board 1 is configured by a glass epoxy substrate. This causes the brightness and the darkness of the electrodes 3 and the circuit board 1 (more specifically, the base material portion 6 thereof) to be more distinctively observable in the luminance image and thus enables the area of the bright portions (the electrodes 3) to be more accurately specified. This further enhances the accuracy of inspection.

The present disclosure is not limited to the description of the above embodiments but may be implemented, for example, by configurations described below. The present disclosure may also be naturally implemented by applications and modifications other than those illustrated below.

(a) According to the embodiments described above, the determination portion 336 is configured to calculate the area of a part that is not covered with the flux 7 in each of the plurality of electrodes 3 configuring the electrode group 3x. According to a modification, however, the determination portion 336 may be configured to calculate a total area of parts that are not covered with the flux 7 in these electrodes 3. The determination portion 336 may compare the calculated total area with an area threshold value to perform defective/non-defective determination with regard to the application state of the flux 7.

(b) According to the embodiments described above, the circuit board 1 is configured by a glass epoxy substrate. The circuit board 1 may, however, be configured by another type of substrate. For example, the circuit board 1 may be configured by a ceramic substrate.

(c) According to the embodiments described above, the flux 7 is transparent or translucent. The flux 7 may, however, be opaque.

According to the embodiments described above, the flux 7 is configured to collectively cover all the plurality of electrodes 3 configuring one electrode group 3x. According to a modification, however, the flux 7 may be configured to individually cover these electrodes 3.

(d) According to the embodiments described above, a BGA is employed as an example of the electronic component 5. The electronic component 5 may, however, be another semiconductor package (for example, CSP (Chip Size Package)).

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1 . . . printed circuit board (circuit board), 3 . . . electrode, 5 . . . electronic component (component), 7 . . . flux, 12 . . . flux application state inspection device, 321 . . . illumination device (irradiation unit), 322 . . . camera (imaging unit), 335 . . . inspection area setting portion (inspection area setting unit), 336 . . . determination portion (determination unit), KR . . . inspection area

What is claimed is:

1. A flux application state inspection device, comprising:
an illumination device that irradiates, with ultraviolet light, a circuit board having electrodes on which a flux capable of absorbing the ultraviolet light is applied;
an imaging device that takes an image of the ultraviolet light radiated to the circuit board; and
a central processing unit (CPU) that:
sets, with a reference portion of the circuit board as a reference, an inspection area on the circuit board for each component to be mounted on the circuit board, wherein the inspection area corresponds to the component and includes two or more of the electrodes on which the component is mounted, and
detects whether an application state of the flux is defective or non-defective, based on the image obtained by the imaging device while the inspection area is irradiated with the ultraviolet light by the illumination device, wherein
the CPU calculates an area of a high-luminance part of the inspection area having luminance equal to or higher than a predetermined luminance threshold value, and detects whether the application state of the flux is defective or non-defective based on the calculated area.

2. The flux application state inspection device according to claim 1, wherein
the ultraviolet light radiated from the illumination device has a wavelength set to be not lower than 100 nm and not higher than 300 nm.

3. The flux application state inspection device according to claim 1, wherein
the imaging device is placed above the circuit board such that an optical axis of the imaging device is perpendicular to the circuit board, and
the ultraviolet light radiated from the illumination device to the circuit board has an incident angle of not less than 0 degree and not greater than 30 degrees.

4. The flux application state inspection device according to claim 1, wherein
the flux application state inspection device is used for inspecting the flux that is transparent or translucent.

5. The flux application state inspection device according to claim 1, wherein
the flux application state inspection device is used for inspecting the flux that is applied to an electrode of a glass epoxy substrate used for the circuit board.

6. A flux application state inspection method, comprising:
an irradiation process of irradiating, with ultraviolet light, a circuit board having electrodes on which a flux capable of absorbing the ultraviolet light is applied;
an imaging process of taking an image of the ultraviolet light radiated to the circuit board;
an inspection area setting process of setting, with a reference portion of the circuit board as a reference, an inspection area on the circuit board for each component to be mounted on the circuit board, wherein the inspection area corresponds to the component and includes two or more of the electrodes on which the component is mounted, and
a detection process of detecting whether an application state of the flux is defective or non-defective, based on the image obtained by the imaging process while the inspection area is irradiated with the ultraviolet light by the irradiation process, wherein
the detection process calculates an area of a high-luminance part of the inspection area having luminance equal to or higher than a predetermined luminance threshold value, and detects whether the application state of the flux is defective or non-defective based on the calculated area.
